(19) United States
(12) Patent Application Publication
(10) Pub. No.: US 2023/0100966 A1
(43) Pub. Date: Mar. 30, 2023

(54) PROCESSOR COOLING WITH PHASE CHANGE MATERIAL FILLED SHELL

(71) Applicant: HEWLETT-PACKARD DEVELOPMENT COMPANY, L.P., Spring, TX (US)

(72) Inventors: Robert Lee CRANE, Fort Collins, CO (US); Andrew L. WILTZIUS, Fort Collins, CO (US); Jack Hui HE, Fort Collins, CO (US)

(21) Appl. No.: 17/782,473

(22) PCT Filed: Dec. 3, 2019
(86) PCT No.: PCT/US2019/064335

§ 371 Date: Jun. 3, 2022

(51) Int. Cl. G06F 1/20; H05K 7/20

(52) U.S. Cl. CPC G06F 1/20; H05K 7/20172; H05K 7/20336; H05K 7/20409

(57) ABSTRACT

A processor cooling system may include a processor, a shell having an interior thermally coupled to the processor to receive heat from the processor and a mass of solid to liquid (STL) phase change material filling the shell.

### BACKGROUND

Processors are used in a variety of different computing devices such as laptops, tablet computers, desktop computers, personal data assistants, smart phones, gaming consoles, monitoring systems, a variety of equipment, various machinery and the like. When carrying out computational operations, a processor may generate large amounts of heat. Dissipating the heat to avoid damage to the processor may present many challenges.

### BRIEF DESCRIPTION OF THE DRAWINGS

FIG. 1 is a block diagram schematically illustrating portions of an example processor cooling system.

FIG. 2 is a flow diagram of an example processor cooling method.

FIG. 3 is a side view schematically illustrating portions of an example processor cooling system.

FIG. 4 is a side view schematically illustrating portions of an example processor cooling system, with portions shown in section.

FIG. 5 is a perspective view illustrating portions of an example processor cooling system.

FIG. 6 is a top view illustrating portions of an example processor cooling system, with portions shown in section.

FIG. 7 is a side view illustrating portions of an example processor cooling system, with portions shown in section.

FIG. 8A is a top view schematically illustrating portions of an example processor cooling system, with portions shown in section.

FIG. 8B is a side view schematically illustrating portions of the example processor cooling system of FIG. 8A, with portions shown in section.

Throughout the drawings, identical reference numbers designate similar, but not necessarily identical, elements. The FIGS. are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION OF EXAMPLES

Disclosed are example processor cooling systems and processor cooling methods that offer enhanced cooling capacity for cooling a processor of a computing device. A computing device is any device having a processor. The example processor cooling systems and processor cooling methods may provide enhanced cooling capacity during those periods of time when the processor is emitting higher than expected amounts of heat, such as when the processor is in a higher power transient mode, such as a turbo mode.

The example processor cooling systems and processor cooling methods employ a shell filled with solid to liquid (STL) phase change material to serve as a thermal buffer. During high power transient modes or high transient power excursions by the processor, the phase change material absorbs extra heat output by the processor as the phase change material changes from a solid to a liquid state. Once the processor returns to a steady state and begins to cool, the phase change material changes back to a solid phase. In implementations where the processor is cooled by an air mover, such as a fan, that changes speed in response to temperature changes, the phase change material may reduce fan operating fluctuations and excess fan noise by damping temperature fluctuations.

In an implementation, the shell filled with the STL phase change material comprises a reservoir that receives heat from the processor through a heat pipe extending from the processor into the interior of the shell containing the STL phase change material. In another implementation, the shell filled with the STL phase change material comprises a fin that receives heat from the processor through a heat pipe extending from the processor into the interior of the fin. In an implementation, the shell filled with STL phase change material is formed from a highly thermally conductive material and is in direct contact with the processor.

In some implementations, heat spreading structures may be provided within the shell. For example, thermally conductive baffles may extend within the shell to more uniformly distribute heat throughout the STL phase change material within the shell. In some implementations, the heat spreading structures themselves may contain a STL phase change material. In some implementations, the shell may contain a first phase change material while the thermally conductive baffles contain a second different STL phase change material. In some implementations, multiple fins may receive heat from a heat pipe connected to the processor, wherein different fins contain different STL phase change materials having different compositions. The different STL phase change materials may provide a staged or stepped response to heat fluctuations caused by transient power excursions of the processor.

Disclosed is an example processor cooling system that may include a processor, a shell having an interior thermally coupled to the processor to receive heat from the processor and a mass of solid to liquid (STL) phase change material filling the shell.

Disclosed is an example processor cooling method. The method may include transferring heat from a processor into an interior of a shell and absorbing the heat with a phase change material filling the interior of the shell so as to convert the phase change material from a solid state to a liquid state.

Disclosed is an example processor cooling system that may include a processor, a heat pipe extending from the processor, a heat spreading fin, an air mover to direct airflow across the heat spreading fin, a heat pipe extending from the processor through the heat spreading fin and a mass of solid to liquid phase change material filling a metal shell and receiving heat from the heat pipe.

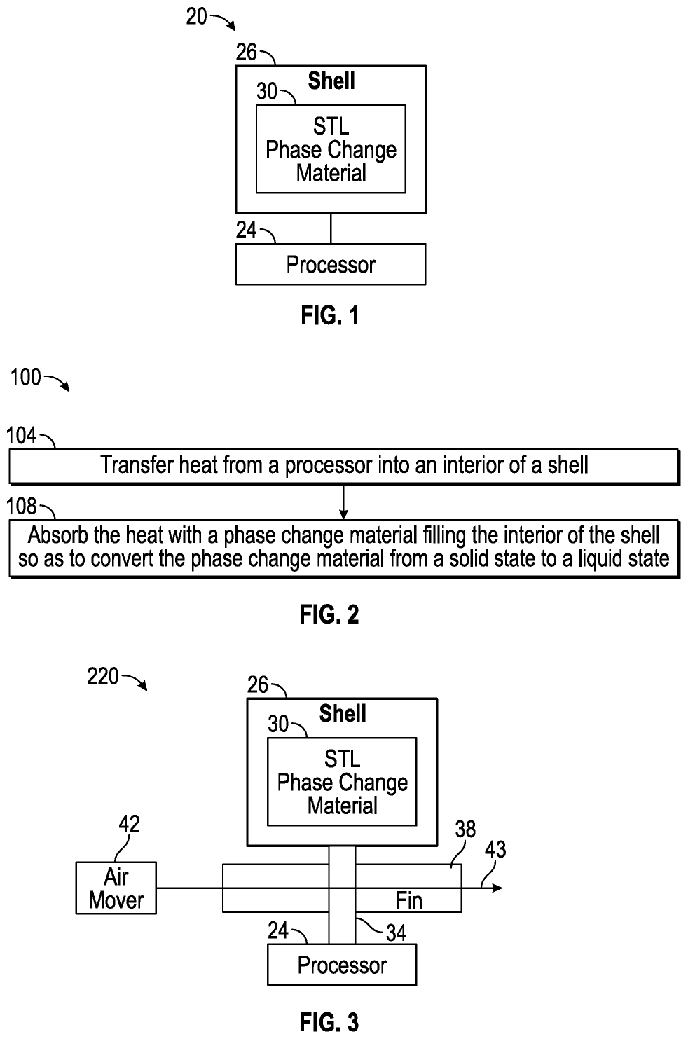

FIG. 1 is a block diagram schematically illustrating portions of an example processor cooling system 20. Processor cooling system 20 provides enhanced processor cooling capacity that may better accommodate fluctuations in the amount of heat output by the processor during higher transient power (“turbo boost”) states. Processor cooling system 20 comprises processor 24, shell 26 and STL phase change material 30.

Processor 24 comprises electronics or electrical circuitry that carry out various computing functions in accordance with instructions in the form of software and/or logic elements. The electrical circuitry may be composed of multiple transistors and electronic components. Processor 24 relies upon the transmission of electrical current to carry out processing functions. The transmission of electrical current across electrically resistive components generates heat. Left unchecked, the heat output by the processor may cause the temperature of the processor and nearby components to rise to a level at which the processor or nearby components may be damaged. Processor cooling system 20 removes excess heat to maintain the temperature of the processor and surrounding components at operationally safe levels.

Shell 26 comprises an enclosure having an interior thermally coupled to processor 24. For purposes of this disclosure, the term “thermally coupled” shell mean that two or more structures are connected directly to one another or are connected to one another by intermediate structures such that heat may flow from one structure to the other structure. With respect to processor 24 and the interior of shell 26 being “thermally coupled, the phrase refers to heat being transmittable from processor 24, directly or indirectly, to the interior of shell 26.

In an implementation, the interior of shell 26 is thermally coupled to processor 24 by thermally conductive rods or bars, such as metal rods or bars, which extend from processor 24 into the interior of shell 26. In an implementation, the interior of shell 26 is thermally coupled to processor 24 by a heat pipe or multiple heat pipes. In some implementations, the walls of shell 26 may be formed from a metal or other thermally conductive material which conducts heat from the heat pipe to the interior of shell 26. For example, in an implementation, shell 26 may be formed from copper. In other implementations, shell 26 may be formed from other materials. Examples of such materials include, but are not limited to, copper alloys, aluminum alloys; magnesium alloys; titanium alloys, high temperature and thermally conductive plastics; steel alloys; ceramics, carbon derivatives (graphite, graphene, diamond), and composite construction (metal/plastic combinations). In some implementations, the walls of shell 26 may be formed from metal or other thermally conductive material which is in direct contact with processor 24, without relying upon a heat pipe.

In some implementations, shell 26 may be in the form of a reservoir container. In such an implementation, the reservoir container may itself contain heat spreading structures, such as thermally conductive baffles throughout for more uniformly distributing heat throughout the interior of shell 26. In another implementation, shell 26 may be in the form of a thermally conductive fin across which air is moved by an air mover to facilitate heat dissipation.

STL phase change material 30 comprises a mass (in contrast to a film or coating) filling the interior of shell 26. STL phase change material 30 has a sufficient mass so as to absorb 50 W or more for a time period of 30 seconds or more. In an implementation, STL phase change material 30 comprises a mass of paraffin. In other implementations, STL phase change material 30 may comprise multiple types of paraffins, each with different melting points; inorganic salt hydrates. In an implementation, STL phase change material 30 has a melting point, a temperature at which material 30 changes from a solid phase or state to a liquid phase or state, of between 50 degrees C. and 100 degrees C. In an implementation, STL phase change material 30 has a melting point of between 60 degrees C. and 90 degrees C. In yet another implementation, STL phase change material 30 has a melting point of between 66 degrees C. and 72 degrees C.

Shell 26 and the contained STL phase change material 30 serve as a thermal buffer. During high power transient modes or high transient power excursions by processor 24, the phase change material 30 absorbs extra heat output by the processor 24 as the phase change material 30 changes from a solid to a liquid state. Once the processor 24 returns to a steady state and begins to cool, the phase change material 30 changes back to a solid phase or state. In implementations where the processor 24 is cooled by an air mover, such as a fan, that changes speed in response to temperature changes, the phase change material 30 may reduce fan operating fluctuations and excess fan noise by damping temperature fluctuations.

FIG. 2 is a flow diagram of an example processor cooling method 100. Method 100 cools a processor to reduce the likelihood of processor becoming overheated and being damaged. Method 100 offers thermal damping during times in which the processor may be emitting excess amounts of heat due to high or intense usage. Although method 100 is described in the context of being carried out by system 20, it should be appreciated that method 100 may likewise be carried out with any of the following described systems or with similar systems.

As indicated by block 104, heat is transferred from processor 24 into an interior of a shell, such as shell 26. Such heat transfer may be carried out using a heat pipe or a plurality of heat pipes that extend from the processor to the interior of shell 26 or to a thermally conductive member that is thermally coupled to the interior of shell 26, such as a thermally conductive wall of shell 26. Such a transfer may be carried out by the thermally conductive walls of shell 26 in direct contact with heat emitting surfaces of processor 24.

As indicated by block 108, a STL phase change material filling the interior of shell 26 absorbs the heat originating from processor 24. The absorption of the heat by the phase change material 30 causes phase change material 30 to convert or transition from a solid state to a liquid state. Thereafter, the phase change material may return to its original solid state in response to the amount of heat being transmitted from processor 24 declining and/or in response to cooling of shell 26, wherein the temperature of the STL phase change material 30 within shell 26 drops to a temperature below its melting point.

FIG. 3 is a block diagram schematically illustrating portions of an example processor cooling system 220. FIG. 3 illustrates how heat from processor 24 may be dissipated and may be transmitted to the phase change material 30 within shell 26. System 220 is similar to system 20 described above except the system 220 is specifically illustrated as additionally comprising heat pipe 34, fin 38 and air mover 42. Those remaining components or structures of system 220 which correspond to components or structures of system 20 are numbered similarly and are described above.

Heat pipe 34 thermally couples processor 24 to the interior of shell 26 containing STL phase change material 30. Those portions of heat pipe 34 adjacent to processor 24 comprise an “evaporator” portion of heat pipe 34 where liquid within the heat pipe is changed to a vapor which travels towards shell 26. Those portions of the heat pipe 34 adjacent to shell 26 or extending within the interior of shell 26 comprise a “condenser” portion of heat pipe 24 where heat is discharged or released, causing the vapor to cool and condense, returning to a liquid state and flowing back towards the evaporator portion.

Heat pipe 34 (schematically illustrated) extends through fin 38 on its way to shell 26. Although system 220 is illustrated as having fin 38 in between the processor 24 and shell 26, fin 38 could be placed in any orientation relative to shell 26. Although system 220 is illustrated as having a single fin 38, it should be appreciated that system 220 may have a plurality of fins 38. Although system 220 is illustrated as having a single heat pipe 34, it should be appreciated that system 220 may have a plurality of heat pipes 34 extending from processor 24 to shell 26. Although heat pipe 34 is illustrated as being generally linear, it should be appreciated that heat pipe 34 may be serpentine or have other shapes. For example, heat pipe 34 may extend along a U-shaped path, wherein the lower portion of the “U” extends along and in contact with heat emitting surfaces of processor 24 and wherein the upper portion of the “U” contacts the thermally conductive exterior shell 26 or extend into shell 26. In such an implementation, the lower portion forms the evaporator portion while the upper portion forms the condenser portion of the heat pipe 34.

Fin 38 comprises a heat dissipating structure having a thermally conductive outer skin or surface. In an implementation, fin 38 has a face facing in a direction perpendicular to a direction of airflow produced by air mover 42 and directed across fin 38. In an implementation, the face has a length and/or a width dimension that is greater than a thickness dimension of fin 38. In an implementation, fin 38 may be formed from a thermally conductive material such as copper or other metals. Fin 38 receives heat from heat pipe 34 and spreads the received heat across its large surface area. In an implementation, fin 38 comprise a solid mass of a thermally conductive material, such as a metal. In other implementations, fin 38 may be hollow or may be perforated to provide more heat dissipating surfaces. In some implementations, fin 38 may be hollow and may be filled with STL phase change material 30.

Air mover 42 comprise a device that causes airflow 43 (represented by an arrow 43) across fin 38. In an implementation, air mover 42 comprises a blower or fan. In other implementations, rather than pushing air across fin 38, air mover 42 may draw air across fin 38. The airflow 43 moving across fin 38 absorbs heat from fin 38 and carries such heat away.

In an implementation, the airflow provided by air mover 42 and the cooling provided by fin 38 are sufficient to cool processor 24 during steady-state operation of processor 24 such that processor 24 does not experience a potentially damaging temperature. During such times, STL phase change material 30 remains in a solid state. During higher power transient modes (turbo modes), the demands upon processor 24 may rise. Such increased processing speeds or power may result in excess heat being generated by processor 24. The excess heat is transmitted by heat pipe 34 to the STL phase change material 30 within shell 26. The excess heat is absorbed by the STL phase change material 30, causing the STL phase change material 30 to change from a solid state or phase to a liquid state or phase. In some implementations, heat absorption by material 30 is sufficient such that the temperature of processor 24 (and the surrounding environment being sensed by temperature sensors) does not rise to a level so as to trigger increased airflow from air mover 42. As a result, shell 26 and its contained STL phase change material 30 may reduce fluctuations in the operation of air mover 42 thereby reducing fluctuations in the noise produced by the operation of air mover 42.

As indicated above, in an implementation, shell 26 may be a reservoir or other container containing a volume of STL phase change material 30. In another implementation, shell 26 may itself be another fin 38 which is hollow and contains STL phase change material 30. In some implementations, system 220 may include a mixture of solid fins 38 and fins 38 that are hollow and that contain STL phase change material 30. In some implementations, system 220 may include more than three fins 38 containing STL phase change material 30.

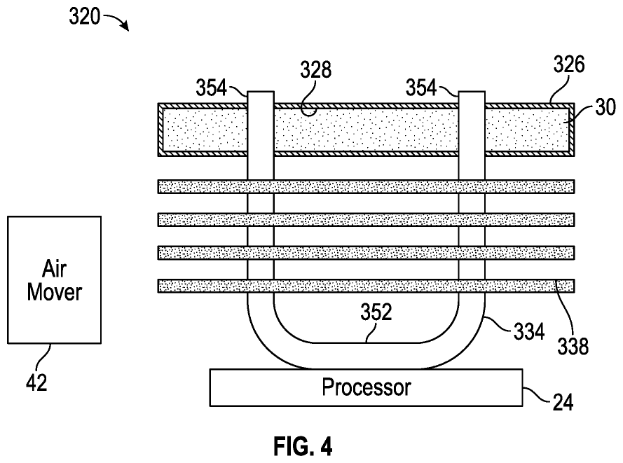

FIG. 4 illustrates portions of an example processor cooling system 320. System 320 is a specific example of system 220. In addition to processor 24 and air mover 42 described above, system 320 specifically comprises shell 326, heat pipe 334 and heat spreading fins 338. The remaining components of system 320 which correspond to components of system 220 are numbered similarly and are described above.

Shell 326 comprises a reservoir chamber generally above processor 24 and fins 338. In an implementation, shell 326 is formed from a metal, facilitating thermal conduction and dissipation of heat. In yet other implementations, shell 326 is formed from a polymer, a ceramic or other material. Shell 326 has an interior 328 filled with a mass (in contrast to a thin-film or coating) of the STL phase change material 30 (described above). As shown in FIG. 4, the STL phase change material 30 fills 75% or more of the available space within interior 328. In an implementation, the STL phase change material 30 fills 95% or more of the available space within interior 328. The STL phase change material 30 continuously extends between portions of heat pipe 334 that extend through interior 328. The STL phase change material continually extends from one portion of heat pipe 334 to another portion of the same heat pipe 334 as well as other heat pipes 334 that may extend through or within interior 328. As a result, shell 326 provides space efficient heat absorbing capacity.

In an implementation, shell 326 contains a sufficient volume of the STL phase change material so as to have a heat absorbing capacity of 50 W or more for a duration of 30 seconds or more. In an implementation, shell 326 contains a volume of paraffin of 400 cm³ or more.

Heat pipe 334 has a general U-shape. Heat pipe 334 extends along a U-shaped path, wherein the lower portion 352 of the “U” extends along and in contact with heat emitting surfaces of processor 24 and wherein the upper portions 354 of the “U” extend into the interior of shell 326, contacting the STL phase change material 30 filling shell 326. In such an implementation, the lower portion 352 forms the evaporator portion while the upper portions 354 form the condenser portion of the heat pipe 334. In implementations where the outer skin of shell 326 is formed from a thermally conductive material, such as a metal, upper portions 354 may alternatively be in thermally conductive contact or run along the outer surfaces of shell 326 rather than passing through shell 326.

Fins 338 comprise thin thermally conductive heat spreading plates through which heat pipe 334 extends. Fins 338 may be formed from a thermally conductive material such as a metal, such as copper. Fins 338 receive heat from the outer thermally conductive surface of heat pipe 334 and spread the heat out for being carried away by the air moved through and between fins 338 by air mover 42.

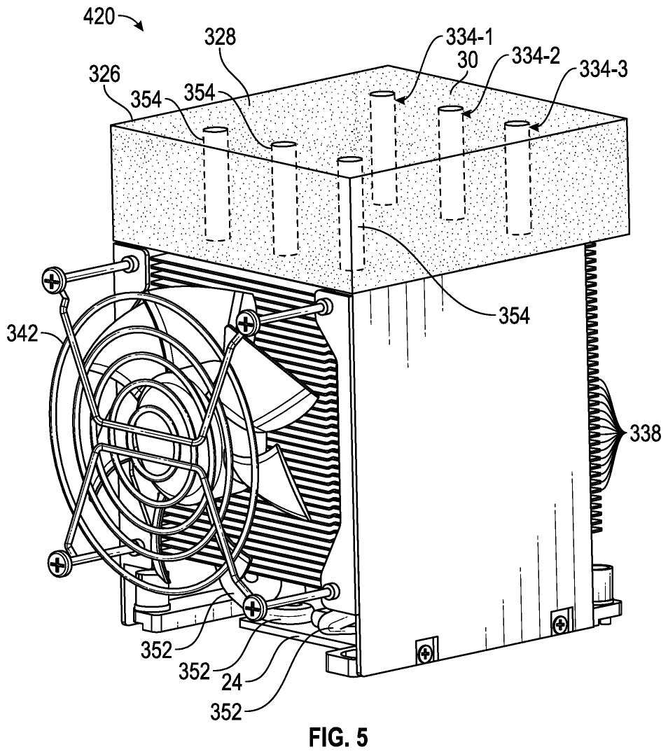

FIG. 5 is a perspective view illustrating portions of an example processor cooling system 420. Processor system 420 is similar to processor system 320 described above except that processor system 420 is specifically illustrated as comprising an array of heat pipes 334-1, 334-2 and 334-3 (collectively referred to as heat pipes 334) and as comprising an air mover 342 in the form of a fan. Those remaining components of system 420 which correspond to components of system 320 are numbered similarly.

As shown by FIG. 5, heat pipes 334 each have a lower portion 352 extending along processor 24 and an upper portion 354 extending into the interior 328 of shell 326 in the form of a reservoir or chamber. Intermediate portions of heat pipes 334 extend through heat spreading fins 338. The multiple condenser ends 354 of heat pipe 334 transmit heat throughout the STL phase change material 30 within interior 328 of shell 326.

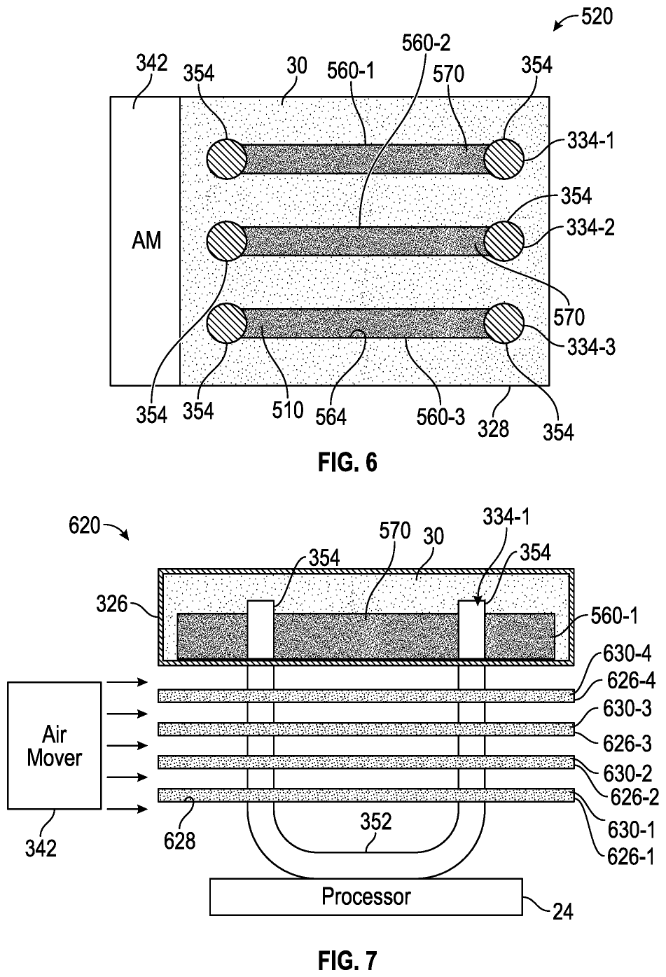

FIG. 6 is a top view illustrating portions of an example processor cooling system 520. Processor cooling system 520 is similar to system 420 except that system 520 additionally comprises heat spreaders 560-1, 560-2 and 560-3 (collectively referred to as heat spreaders 560). Those remaining components of system 520 which correspond to components of system 420 are numbered similarly and/or are shown in FIG. 5.

Heat spreaders 560 comprise structures extending within interior 328, within and through STL phase change material 30. Heat spreaders 560 are formed from a thermally conductive material, such as a metal, such as copper. In the example illustrated, heat spreaders 560 comprise heat spreading baffles or panels extending between and connected to opposite ends of a corresponding one of heat pipes 334. Heat spreader 560-1 extends between opposite ends 354 of heat pipe 334-1. Heat spreader 560-2 extends between opposite ends of heat pipe 334-2. Heat spreader 560-3 extends between opposite ends of heat pipe 334-3. Heat spreaders 560 distribute heat from ends 354 throughout material 30 within interior 328, increasing the response time and thermal damping provided by STL phase change material 30.

In the example illustrated, each of heat spreaders 560 is hollow, having an interior 564 filled with an STL phase change material 570. In an implementation, STL phase change material 570 has the same composition as STL phase change material 30 except that heat is first thermally conducted through the thermally conductive walls of the heat spreader 560 before heating the material 570. This may result in the STL phase change material 570 taking a longer amount of time before reaching its melting point to absorb heat. As a result, system 520 may offer a multistage or stepped thermal damping.

In an implementation, the STL phase change material 570 within each of heat spreaders 560 has a different composition as compared to the composition of the STL phase change material 30. In an implementation, the STL phase change material 570 has a melting point that is greater than the melting point of the STL phase change material 30, wherein an initial extent of heat is absorbed by material 30 and wherein a greater amount of heat beyond the initial amount of heat is then absorbed by STL phase change material 570. In yet another implementation, the STL phase change material 570 has a melting point that is less than the melting point of the STL phase change material 30. As a result, heat transmitted by heat pipes 354 may initially melt STL phase change material 570 which has a lower volume or mass of material as compared to that contained in the remainder of interior 328. Thereafter, the larger mass of STL phase change material 30 may begin to melt and absorb heat. In yet other implementations, some or all of the heat spreaders 560 may omit an STL phase change material. For example, in an implementation, each of the heat spreaders 560 may comprise a thermally conductive solid panel of metal.

FIG. 7 is a sectional view illustrating portions of an example processor cooling system 620. System 620 is similar to system 520 described above except that system 620 comprises additional shells 626-1, 626-2, 626-3 and 626-4 (collectively referred to as shells 626) in place of fins 338. Those remaining components of system 620 which correspond to components of system 520 are numbered similarly and/or are shown in FIGS. 5 and 6.

Shells 626-1, 626-2, 626-3 and 626-4 are similar to fins 338 except that shells 626 have hollow interiors 628 which are filled with STL phase change materials 630-1, 630-2, 630-3 and 630-4, respectively. Each of shells 626 has an outer wall formed from a thermally conductive material such as a metal, such as aluminum or copper. Shells 626 are oriented so as to extend substantially perpendicular to intersecting portions of the heat pipes 334 (some which are shown in FIG. 6) and so as to be spaced from one another to facilitate airflow, generally by air mover 342, through and across the sets of shells 626. In an implementation, shells 626 each extend in planes parallel to the plane of processor 24. Although system 620 is illustrated as comprising four shells 626, it should be appreciated that system 620 may include a plurality of such shells.

In the example illustrated, shells 626 are spaced and stacked between processor 24 and shell 326, conserving space. In addition, because shells 626 are stacked and spaced between processor 24 and shell 326, initial amounts of heat are first absorbed by the thermally conductive shells 626, resulting in the heat being spread across the outer skin of shells 626 before being dissipated by the airflow generated by air mover 342. Until the current amount of heat being generated by processor 24 can no longer be dissipated by the airflow passing between shells 626, the amount of heat thermally conducted to the interiors 628 into the phase change materials 630 may be insufficient to cause a phase change. The STL phase change material within shells 626 may remain in a solid state.

However, during processing and power surges, the heat generated by processor 24 may spike such that the airflow between shells 626 may be insufficient to maintain the temperature of processor 24. This may result in the temperature of shell 626 rising to a point such that the STL phase change material 630 within shells 626 changes state absorbing heat to provide an additional stepped or staged cooling. In some implementations, the STL phase change material 630-1 in shell 626-1 may absorb heat and change phase prior to the STL phase change material 630-2 in shell 626-2. Likewise, the STL phase change material 630-2 may absorb heat and change phase prior to the STL phase change material 630-3 in shell 626-3. The STL phase change material 630-3 may absorb heat and change phase prior to the STL phase change material 630-4 in shell 626-4, and so forth.

Once the heat has been sufficiently absorbed to change the STL phase change materials 630 in fins 626, a sufficient amount of heat may be transmitted to shell 326 and its internal heat spreaders 560 (some which are shown in FIG. 6). Thereafter, the STL phase change materials 30 and 570 may begin to absorb heat and change phase. As described above, the order in which the phase change materials 570 in the heat spreaders 560 changes phases as compared to the STL phase change material 30 in shell 326 may depend upon the composition of the STL phase change materials 570 in spreaders 560 relative to the composition of the STL phase change material 30 in shell 326 about spreaders 570. Thus, system 620 provides a multi-stepped or multistage cooling in which different amounts of heat generated by processor 24 may sequentially trigger phase changes and heat absorption.

The STL phase change materials 630 may be similar to the STL phase change materials 30 and 570 described above in that STL phase change materials 630 may change phase or state from a solid to a liquid in response to the temperature equaling the melting point of the STL phase change material. Examples of a STL phase change material include, but are not limited to, paraffin, waxes, organic acid salts, inorganic salt hydrates. In an implementation, STL phase change materials 630 have similar compositions and similar melting points. In another implementation, the STL phase change material 630 contained within and filling the different shells 626 have different compositions and different melting points. Such an implementation results in system 620 being able to more precisely react in a stepwise manner to power and heat surcharges of processor 24.

In an implementation, the STL phase change materials 630 within shells 626-1 to 626-4 have increasingly higher melting points as the shells 626 approach shell 326, with the STL phase change material 630-4 within shell 626-4 having the highest melting point of the STL phase change materials 630. In another implementation, the STL phase change materials 630 within shells 626-1 to 626-4 have an increasingly higher melting point as the shells 626 approach processor 24 with the STL phase change material 630-1 having the highest melting point. In an implementation, the STL phase change materials 630 may have different melting points as compared to the STL phase change materials 570 or the STL phase change material 30.

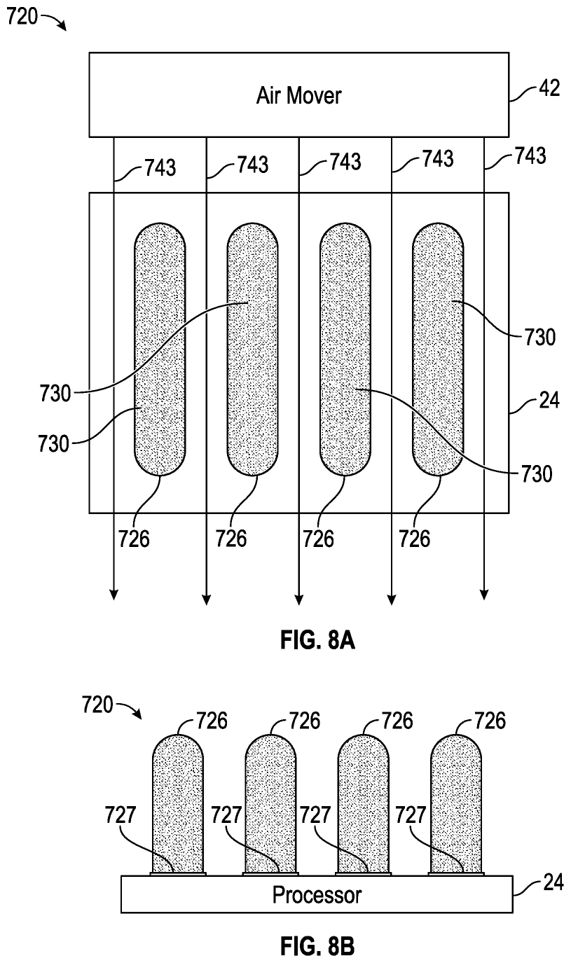

FIGS. 8A and 8B illustrate portions of an example processor cooling system 720. FIGS. 8A and 8B illustrate a process cooling system in which heat pipes 334 are omitted, wherein heat spreading fins, through which air is moved for cooling, are in direct contact with the heat generating source, processor 24 and contain STL phase change material. Cooling system 720 comprises processor 24, air mover 42, shells 726 and STL phase change material 730.

Processor 24 and air mover 42 are described above. Shells 726 comprise hollow containers or heat spreading fins of a thermally conductive material such as a metal, such as copper or aluminum. Shells 726 are filled with STL phase change material 730. As shown by FIG. 8A, shells 726 are spaced from one another and extend generally parallel to one another across from air mover 42. As indicated by arrows 743 airflow generated by air mover 42 passes between and across shells 726 to absorb and carry away heat.

As shown by FIG. 8B, shells 726 have lower walls or floors 727 that are in thermal contact with heat emitting surfaces of processor 24. In an implementation, floor 727 may be in direct contact with the surface of processor 24. In another implementation, intermediate thermally conductive materials may be sandwiched between processor 24 and floor 727. Heat generated by processor 24 is initially conducted to the thermally conductive material forming floor 727 and the remainder of shell 726, wherein the airflow indicated by arrow 743 absorbs and carries heat absorbed and spread by shell 726. Because the STL phase change materials 730 contained within each of shell 726 has a lower thermal conductivity as compared to the material forming shell 726 and the intervening floor 727, the heat more quickly spreads along the surface of shell 726 for dissipation as compared to the transmission of heat to the STL phase change material 730.

During processing and power surges which result in excess heat being generated, the airflow through shells 726 may not be sufficient to maintain a temperature below a chosen target temperature. The excess heat may result in a rise in the temperature to a level above the melting point of the STL phase change material 730. At such time, the STL phase change material 730 may absorb heat as it changes phase to a liquid state. Thus, system 720 provides a multistage or multi-step cooling of processor 24.

In an implementation, the STL phase change material 730 in each of fins 726 has the same composition, the same melting point. In other implementations, some of fins 726 may be filled with a first STL phase change material while others of fins 76 are filled with a second STL phase material having a different composition and/or a different melting point as compared to the first STL phase change material. By doing so, additional heat absorption trigger points may be provided for sequential stages of cooling for processor 24 dependent upon the current amount of heat being generated by processor 24.

Although the present disclosure has been described with reference to example implementations, workers skilled in the art will recognize that changes may be made in form and detail without departing from this disclosure. For example, although different example implementations may have been described as including features providing various benefits, it is contemplated that the described features may be interchanged with one another or alternatively be combined with one another in the described example implementations or in other alternative implementations. Because the technology of the present disclosure is relatively complex, not all changes in the technology are foreseeable. The present disclosure described with reference to the example implementations and set forth in the following claims is manifestly intended to be as broad as possible. For example, unless specifically otherwise noted, the claims reciting a single particular element also encompass a plurality of such particular elements. The terms “first”, “second”, “third” and so on in the claims merely distinguish different elements and, unless otherwise stated, are not to be specifically associated with a particular order or particular numbering of elements in the disclosure.

What is claimed is:

1. A processor cooling system comprising:
a processor;
a shell having an interior thermally coupled to the processor to receive heat from the processor;
a mass of solid to liquid (STL) phase change material filling the shell.

2. The cooling system of claim 1, wherein the shell is remote from the processor, the system further comprising a heat mover to move heat from the processor to the interior of the shell.

3. The cooling system of claim 2, wherein the heat mover comprises a heat pipe.

4. The cooling system of claim 2, wherein the heat mover comprises a thermally conductive rod.

5. The cooling system of claim 2, wherein the heat mover comprises two distinct portions extending within the shell through the STL phase change material filling the shell.

6. The cooling system of claim 5 comprising a second heat mover to move heat from the processor to the shell, wherein the first heat mover and the second heat mover each extend within the shell through the STL phase change material filling the shell.

7. The cooling system of claim 2, wherein the shell comprises a heat spreading fin and wherein the cooling system further comprises an air mover for directing airflow across the heat spreading fin.

8. The cooling system of claim 7 further comprising a second heat spreading fin filled with a second STL phase change material, wherein the heat mover extends through the second STL phase change material within the second heat spreading fin.

9. The cooling system of claim 8, wherein the second STL phase change material has a different composition than the first STL phase change material.

10. The cooling system of claim 2 further comprising a heat spreader connected to the heat mover and extending through the STL phase change material within the shell.

11. The cooling system of claim 1 further comprising a second shell having a second interior thermally coupled to the processor, the second shell filled with a second STL phase change material having a different composition than the first STL phase change material.

12. The cooling system of claim 1 further comprising a heat spreader within the shell and extending through the STL phase change material within the shell.

13. A processor cooling method comprising:
transferring heat from a processor into an interior of a shell;
absorbing the heat with a phase change material filling the interior of the shell so as to convert the phase change material from a solid state to a liquid state.

14. The method of claim 13, wherein the heat is transferred from the processor into the interior of the shell with a heat pipe.

15. A processor cooling system comprising:
a processor;
a heat pipe extending from the processor;
a heat spreading fin;
an air mover to direct airflow across the heat spreading fin;
a heat pipe extending from the processor through the heat spreading fin; and
a mass of solid to liquid phase change material filling a metal shell and receiving heat from the heat pipe.
